(19) United States
(12) Patent Application Publication
(10) Pub. No.: US 2005/0112877 A1
(43) Pub. Date: May 26, 2005

(54) Method of manufacturing a semiconductor device

(76) Inventor: Hideshi Miyajima, Yokohama-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/972,389

(22) Filed: Oct. 26, 2004

(30) Foreign Application Priority Data
Oct. 27, 2003 (JP) 2003-366118

(51) Int. Cl. H01L 21/4763; H01L 21/44

(52) U.S. Cl. 438/687

(57) ABSTRACT

Disclosed is a method of manufacturing a semiconductor device comprising preparing a workpiece, which has a first insulating film containing carbon and hydrogen, and a copper wiring, and reducing an oxide formed on a surface of the copper wiring by using plasma with the workpiece cooled.

### CROSS-REFERENCE TO RELATED APPLICATIONS

This application is based upon and claims the benefit of priority from prior Japanese Patent Application No. 2003-366118, filed Oct. 27, 2003, the entire contents of which are incorporated herein by reference.

### BACKGROUND OF THE INVENTION

1. Field of the Invention

The present invention relates to a method of manufacturing a semiconductor device.

2. Description of the Related Art

As semiconductor devices, such as semiconductor integrated circuits, have been finer, signal propagation delay, resulting from wiring resistance and interwiring capacitance, has been a serious problem. Therefore, it is important to reduce the wiring resistance and the interwiring capacitance.

For reduction of the wiring resistance, use of a copper wiring having a low resistivity has been proposed. For reduction of the interwiring capacitance, use of an interlayer insulating film having a low dielectric constant has been proposed. In general, a damascene wiring, which is formed by filling a trench in an interlayer insulating film with copper, is used as a copper wiring. A low dielectric constant insulating film, containing at least carbon and hydrogen, is generally used as an interlayer insulating film. Further, a stopper insulating film is formed on the copper wiring and the interlayer insulating film by plasma CVD in general. The stopper insulating film functions to prevent copper in the copper wiring from diffusing into the upper layer. It also functions as an etching stopper when the interlayer insulating film formed on the upper side is etched.

When the copper wiring as described above is used, there is a problem that the surface of the copper wiring is oxidized in the atmosphere. When a copper oxide layer is formed on the surface of the copper wiring, the adhesion between the stopper insulating film and the copper wiring is reduced, resulting in a deleterious effect on the characteristics or reliability of the semiconductor device. To prevent this, before forming the stopper insulating film, it is necessary to reduce the copper oxide formed on the surface of the copper wiring. The reduction is performed by plasma process. Since the stopper insulating film is formed by plasma CVD with the substrate heated, the plasma reduction process is also carried out in a process chamber for forming the stopper insulating film with the substrate heated.

However, when the plasma reduction process is performed in a heating state, an organic component contained in the low dielectric constant insulating film (interlayer insulating film) is decomposed by active hydrogen in the plasma atmosphere and is removed as a gas, such as CH₄. Therefore, an OH group is introduced to the surface of the low dielectric constant insulating film, thereby forming a so-called damage layer, which is high in moisture absorbency. As a result, a problem occurs: for example, the damage layer increases a leakage current between wirings.

U.S. 2001/0003064 A1 proposes a method, in which plasma processing to remove the copper oxide layer on the surface of a copper wiring is performed at a temperature lower than the film forming temperature of a CVD insulating film formed on the copper wiring, in order to prevent coagulation of copper caused by migration on the surface of the copper wiring. However, according to the proposal, the substrate is simply lifted up from the heated support stage when the plasma processing is performed. For this reason, the temperature of the substrate in the plasma processing cannot be fully lowered. Therefore, it is difficult to prevent formation of the damage layer described above, or to prevent deterioration of the characteristics or reliability of the semiconductor device caused by the formation of the damage layer.

As described above, the use of the copper wiring and the low dielectric constant insulating film is proposed from the viewpoint of suppressing the signal propagation delay caused by the wiring resistance and the interwiring capacitance. However, the conventional art has the problem that a damage layer is formed on the surface of the low dielectric constant insulating film in the plasma reduction process for removing the copper oxide layer on the surface of the copper wiring, and the leakage current between the wirings is increased by the damage layer, with the result that the characteristics and reliability of the semiconductor device is considerably deteriorated.

### BRIEF SUMMARY OF THE INVENTION

According to an aspect of the present invention, there is provided a method of manufacturing a semiconductor device comprising: preparing a workpiece, which has a first insulating film containing carbon and hydrogen, and a copper wiring; and reducing an oxide formed on a surface of the copper wiring by using plasma with the workpiece cooled.

### BRIEF DESCRIPTION OF THE SEVERAL VIEWS OF THE DRAWING

FIG. 1 is a schematic view showing a structure of an apparatus for manufacturing a semiconductor device according to an embodiment of the present invention.

FIGS. 2 to 4 are schematic cross-sectional views showing steps of manufacturing the semiconductor device according to the embodiment of the present invention.

FIG. 5 is a flowchart showing a method for manufacturing the semiconductor device according to the embodiment of the present invention.

### DETAILED DESCRIPTION OF THE INVENTION

An embodiment of the present invention will be described with reference to the accompanying drawings.

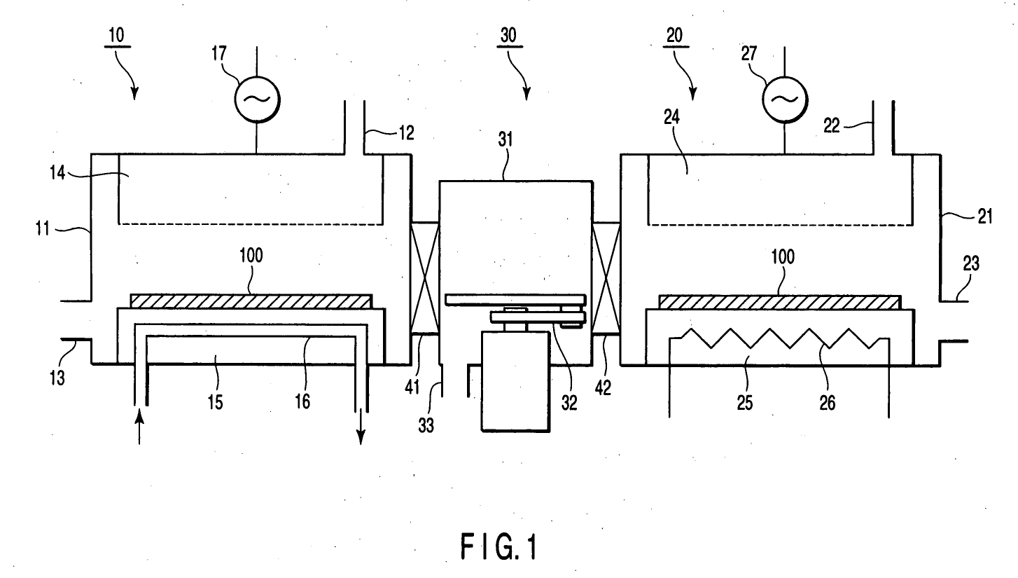

FIG. 1 is a schematic view showing a structure of an apparatus (an apparatus for manufacturing a semiconductor device) used in the embodiment. The apparatus comprises a preprocessing unit (first processing unit) 10, a film forming unit (second processing unit) 20 and a transfer unit 30.

The preprocessing unit 10 performs a reduction process by means of plasma with respect to a surface of a copper wiring to remove a copper oxide layer formed on the surface of the copper wiring. The preprocessing unit 10 comprises a process chamber 11, a gas introducing port 12, an exhaust port 13, a gas dispersion plate 14 (also serving as an upper electrode), a support stage 15 (also serving as a lower electrode), a cooling mechanism 16 and a high-frequency power source 17.

The gas introducing port 12 is connected to the gas dispersion plate 14. The gas introduced through the gas introducing port 12 is supplied into the process chamber 11 via the gas dispersion plate 14. The cooling mechanism 16, through which a cooing liquid circulates, is provided in the support stage 15. The cooling mechanism 16 cools the support stage 15, and a substrate (semiconductor wafer) 100, as a workpiece, disposed on the support stage 15 is cooled. The high-frequency power source 17 supplies high-frequency power to the gas dispersion plate (upper electrode) 14. The high-frequency power causes plasma to be generated in the process chamber 11, thereby removing the copper oxide layer on the surface of the copper wiring provided with the substrate 100.

The film forming unit 20 is used to form a stopper insulating film (to be descried later) on the substrate 100, which has been subjected to the plasma reduction process in the preprocessing unit 10. The film forming unit 20 comprises a process chamber 21, a gas introducing port 22, an exhaust port 23, a gas dispersion plate 24 (also serving as an upper electrode), a support stage 25 (also serving as a lower electrode), a heating mechanism 26 and a high-frequency power source 27.

The gas introducing port 22 is connected to the gas dispersion plate 24. The gas introduced through the gas introducing port 22 is supplied into the process chamber 21 via the gas dispersion plate 24. The heating mechanism (resistance heating mechanism) 26 is provided in the support stage 25. The heating mechanism 26 heats the support stage 25, and the substrate (semiconductor wafer) 100 disposed on the support stage 25 is heated. The high-frequency power source 27 supplies high-frequency power to the gas dispersion plate (upper electrode) 24. The high-frequency power causes plasma to be generated in the process chamber 21, thereby forming a stopper insulating film on the substrate 100.

The transfer unit 30 is arranged between the preprocessing unit 10 and the film forming unit 20. The substrate 100 is transferred from the preprocessing unit 10 to the film forming unit 20 by a transfer mechanism 32 provided in a transfer chamber 31. Air in the transfer chamber 31 is exhausted through an exhaust port 33, so that the substrate 100 can be transferred from the preprocessing unit 10 to the film forming unit 20 without being exposed to the atmosphere. A valve 41, which can be opened and closed, serves as a partition between the process chamber 11 and the transfer chamber 31, and a valve 42, which can be opened and closed, serves as a partition between the process chamber 21 and the transfer chamber 31.

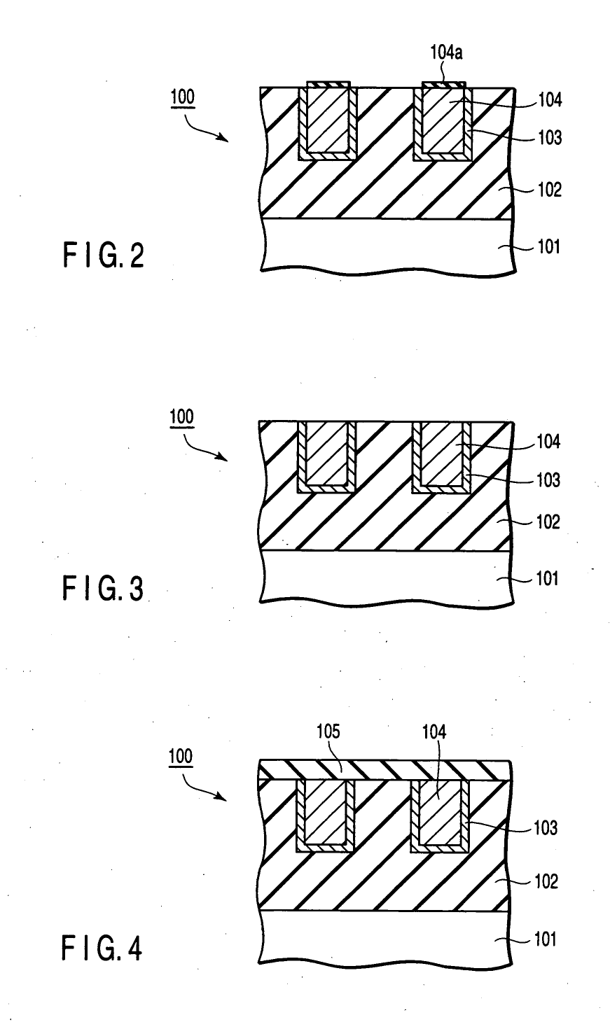

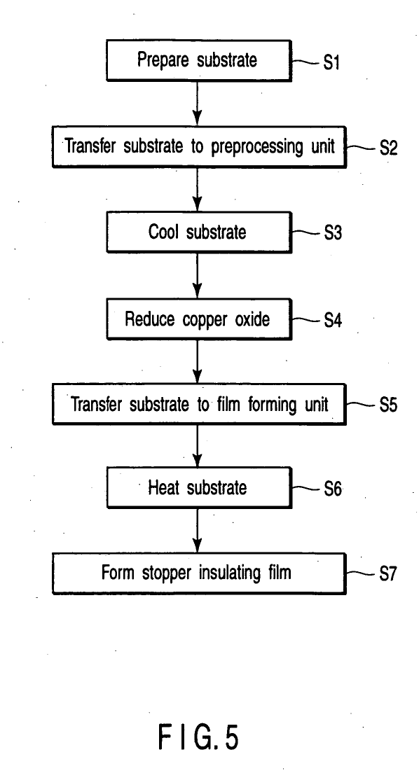

A method for manufacturing a semiconductor device using the above apparatus shown in FIG. 1 will be described below. FIGS. 2 to 4 are schematic cross-sectional views showing the manufacturing method according to the embodiment of the present invention. FIG. 5 is a flowchart for explaining the manufacturing method.

First, as shown in FIG. 2, the substrate 100 as a workpiece is prepared (S1). The substrate 100 includes a semiconductor substrate 101, a low dielectric constant insulating film (first insulating film) 102 as an interlayer insulating film, a barrier metal film 103 and a copper wiring 104. Actually, semiconductor elements, such as MIS transistors, are formed on the semiconductor substrate 101. Another insulating film, wiring or the like may be formed between the semiconductor substrate 101 and the low dielectric constant insulating film 102. As shown in FIG. 2, the surfaces of the low dielectric constant insulating film 102 and the copper wiring 104 are substantially exposed. Since copper is easily oxidized in the atmosphere, a copper oxide layer 104a is formed on the surface of the copper wiring 104.

An insulating film containing at least carbon and hydrogen is used as the low dielectric constant insulating film 102. In this embodiment, an insulating film containing silicon, oxygen, carbon and hydrogen (hereinafter referred to as an SiCO:H film) is used as the low dielectric constant insulating film 102. For example, an organic insulating film formed by means of plasma CVD, using an organic silane gas (alkylsilane gas) and O₂ gas as source gas, can be used as the low dielectric constant insulating film 102. This low dielectric constant insulating film is formed by introducing a methyl into a normal silicon oxide film (SiO₂ film). The relative dielectric constant of the film is about 2.2 to 3.0, which is considerably smaller than that of the normal SiO₂ film (about 3.9). A damascene wiring is used as the copper wiring 104. The damascene wiring is formed by filling a trench formed in the low dielectric constant insulating film 102 with copper.

Then, as shown in FIG. 3, the copper oxide layer 104a formed on the surface of the copper wiring 104 is removed by the plasma reduction process. This step will be described in detail below.

First, the substrate 100 is transferred into the process chamber 11 of the preprocessing unit 10 (S2) and disposed on the support stage 15. The substrate 100 disposed on the support stage 15 is cooled by the cooling mechanism 16 provided in the support stage 15 (S3). In this embodiment, the cooling temperature is set to −50° C. The support stage 15 may be cooled by the cooling mechanism 16 in advance before the substrate 100 is disposed, or after the substrate 100 is disposed. To reduce the manufacturing time, it is preferable that the support stage 15 be cooled before the substrate 100 is disposed.

After the process chamber 11 is evacuated, NH₃ gas and N₂ gas are introduced into the process chamber 11 through the gas introducing port 12. The flow rates of the NH₃ gas and the N₂ gas are respectively 500 sccm and 5000 sccm. The pressure in the process chamber 11 is regulated to 5 Torr. The high-frequency power source 17 supplies high-frequency power of 200 W at 13.56 MHz to the process chamber 11, and the reduction process by plasma is performed for 20 seconds. This process reduces the copper oxide layer 104a formed on the surface of the copper wiring 104 (S4). More specifically, the reduction process is carried out with active hydrogen generated by NH₃ plasma, and the copper oxide (CuO) is reduced to Cu.

During the above plasma processing, the surface of the low dielectric constant insulating film 102 is also exposed to the plasma atmosphere. However, since the substrate 100 is cooled, reaction between the active hydrogen in the plasma atmosphere and the organic component in the low dielectric constant insulating film 102 can be suppressed. As a result, it is possible to prevent the problem that the organic component in the low dielectric constant insulating film 102 is decomposed and removed by the active hydrogen in the plasma atmosphere. Consequently, formation of the damage layer on the surface of the low dielectric constant insulating film 102 can be suppressed.

The substrate 100, which has been plasma-processed as described above, is transferred to the transfer chamber 31 by the transfer mechanism 32. It is further transferred from the transfer chamber 31 to the process chamber 21 by the transfer mechanism 32 (S5). Since the substrate 100 is not exposed to the atmosphere during the transfer step, a new copper oxide layer is not formed on the surface of the copper wiring 104.

Thereafter, as shown in FIG. 4, a stopper insulating film (second insulating film) 105 is formed on the surface of the low dielectric constant insulating film 102 and the copper wiring 104. The stopper insulating film 105 functions to prevent copper in the copper wiring 104 from diffusing into the upper layer. It also functions as an etching stopper when the interlayer insulating film formed on the upper side is etched. The step of forming the stopper insulating film will be described in detail below.

The substrate 100 transferred into the process chamber 21 is disposed on the support stage 25. The substrate 100 disposed on the support stage 25 is heated by the heating mechanism 26 in the support stage 25 (S6). In this embodiment, the heating temperature is set to 350° C. The support stage 25 may be heated by the heating mechanism 26 in advance before the substrate 100 is disposed, or after the substrate 100 is disposed. To reduce the manufacturing time, it is preferable that the support stage 25 be heated before the substrate 100 is disposed. A heating mechanism may also be provided in the transfer chamber 31, where the substrate 100 may be heated before being transferred to the process chamber 21.

After the process chamber 21 is evacuated, an organic silane gas (alkylsilane gas) and NH₃ gas are introduced into the process chamber 21 through the gas introducing port 22. The flow rates of the organic silane gas and the NH₃ gas are respectively 200 sccm and 400 sccm. The pressure in the process chamber 21 is regulated to 5 Torr. The high-frequency power source 27 supplies high-frequency power of 400 W at 13.56 MHz to the process chamber 21, and the film forming process by plasma (plasma CVD process) is performed for 40 seconds. This film forming process forms a 50 nm thick film containing silicon, carbon, nitrogen and hydrogen (hereinafter referred to as an SiCN:H film) as the stopper insulating film 105 on the surface of the low dielectric constant insulating film 102 and the copper wiring 104 (S7).

The sample obtained by the method described above was subjected to measurement of a leakage current characteristic between adjacent copper wirings. The width of the copper wiring and the distance between the adjacent copper wirings (space width) were both 100 nm. When an electric field of 1 MV/cm was applied between the copper wirings, the leakage current was 9.1×10⁻¹¹ A/cm².

As a comparative example, a sample was produced by performing a plasma reduction process in a process chamber at 350° C., and thereafter forming a stopper insulating film in the same chamber at 350° C. In this case, the leakage current was 2.5×10⁻⁸ A/cm², which was considerably greater than that in the above embodiment. In the case where the plasma reduction process was performed at room temperature, the leakage current was as high as 5.5×10⁻⁹ A/cm². Generally, in terms of the characteristics and reliability of the device, it is preferable that the leakage current be about 1.0×10⁻¹⁰ A/cm² or lower. Therefore, if the plasma reduction process is performed at room temperature, satisfactory characteristics cannot be obtained. To obtain satisfactory characteristics, it is considered that the substrate be cooled to about 0° C. or lower.

As described above, according to the embodiment, when the copper oxide formed on the surface of the copper wiring is reduced by plasma, the substrate is cooled. Therefore, the reactivity of the surface of the low dielectric constant insulating film relative to plasma is lowered, and formation of the damage layer on the surface of the low dielectric constant insulating film can be suppressed. As a result, the leakage current between adjacent copper wirings can be noticeably reduced. Consequently, a semiconductor device having excellent characteristics and high reliability can be obtained.

Further, in the above embodiment, the reduction process and the film forming process are performed in the different process chambers. Since the reduction process is performed with the substrate cooled and the film forming process is performed with the substrate heated, if the reduction process and the film forming process are performed in the same process chamber, the cooling mechanism and the heating mechanism must be provided in the same support stage, resulting in a complicated apparatus structure. Moreover, since it takes a lot of time to cool the heated support stage or to heat the cooled support stage, the manufacturing time will be increased. According to the embodiment of the present invention, such a problem can be avoided, because the reduction process and the film forming process are performed in the different process chambers.

In the above embodiment, the CVD insulating film formed by plasma CVD is used as the low dielectric constant insulating film. However, a coating film of poly methyl siloxane (MSX), poly methyl silsesquioxane (MXQ) or the like can be used as the low dielectric constant insulating film. Alternatively, a polymer film can be used as the low dielectric constant insulating film. Generally, a film containing carbon and hydrogen can be used as the low dielectric constant insulating film. More specifically, an insulating film containing an organic component having a C—H bond can be used. In terms of the dielectric constant, an insulating film having a relative dielectric constant of 3.0 or smaller can be used as the low dielectric constant insulating film.

Further, in the above embodiment, the film containing silicon, carbon, nitrogen and hydrogen (the SiCN:H film) is used as the stopper insulating film. However, the stopper insulating film may contain at least silicon, carbon and hydrogen. More specifically, it can be a film containing silicon, carbon and hydrogen (SiC:H film) or a film containing silicon, carbon, oxygen and hydrogen (SiCO:H film).

Furthermore, in the above embodiment, the mixture of NH₃ gas and N₂ gas is used in the plasma reduction process. However, a gas containing at least one of NH₃ gas and H₂ gas can be used in the process. For example, a gas containing only NH₃ or H₂, a mixture of H₂ gas and N₂ gas, a mixture of H₂ gas and He gas, or the like can be used. More generally, a gas containing at least a reducing gas containing hydrogen can be used in the plasma reduction process.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of manufacturing a semiconductor device comprising:
preparing a workpiece, which has a first insulating film containing carbon and hydrogen, and a copper wiring; and
reducing an oxide formed on a surface of the copper wiring by using plasma with the workpiece cooled.

2. The method according to claim 1, further comprising forming a second insulating film on the first insulating film and the copper wiring, after reducing the oxide.

3. The method according to claim 2, wherein the second insulating film is formed with the workpiece heated.

4. The method according to claim 3, wherein the oxide is reduced in a first processing unit and the second insulating film is formed in a second processing unit other than the first processing unit.

5. The method according to claim 4, further comprising transferring the workpiece from the first processing unit to the second processing unit without exposing the workpiece to atmosphere, after reducing the oxide.

6. The method according to claim 5, wherein the workpiece is transferred from the first processing unit to the second processing unit via a transfer unit located between the first processing unit and the second processing unit.

7. The method according to claim 4, wherein in reducing the oxide, the workpiece is cooled by a first support portion, which is provided in the first processing unit and supports the workpiece.

8. The method according to claim 7, wherein the first support portion is cooled in advance before it supports the workpiece.

9. The method according to claim 4, wherein in forming the second insulating film, the workpiece is heated by a second support portion, which is provided in the second processing unit and supports the workpiece.

10. The method according to claim 9, wherein the second support portion is heated in advance before it supports the workpiece.

11. The method according to claim 1, wherein the copper wiring is provided in a trench formed in the first insulating film.

12. The method according to claim 1, wherein the first insulating film further contains silicon and oxygen.

13. The method according to claim 1, wherein the first insulating film has a relative dielectric constant of at most 3.0.

14. The method according to claim 1, wherein the first insulating film is formed of an insulating film containing an organic component.

15. The method according to claim 3, wherein the second insulating film contains silicon, carbon and hydrogen.

16. The method according to claim 15, wherein the second insulating film further contains at least one of nitrogen and oxygen.

17. The method according to claim 3, wherein the second insulating film is formed by using plasma.

18. The method according to claim 3, wherein the second insulating film is formed by plasma CVD.

19. The method according to claim 1, wherein the oxide is reduced by using plasma with gas containing at least one of NH₃ gas and H₂ gas.

20. The method according to claim 1, wherein the oxide is reduced by using plasma with the workpiece cooled to 0° C. or lower.
